(19) United States
(12) Patent Application Publication
(10) Pub. No.: US 2026/0301834 A1
(43) Pub. Date: Oct. 1, 2026

(54) MEMORY SYSTEM CONFIGURED FOR CONTROLLING A FUSE ARRAY CIRCUIT

(71) Applicant: SK hynix Inc., Icheon-si Gyeonggi-do (KR)

(72) Inventor: Young Hyun JEON, Icheon-si Gyeonggi-do (KR)

(73) Assignee: SK hynix Inc., Icheon-si Gyeonggi-do (KR)

(21) Appl. No.: 19/283,779

(22) Filed: Jul. 29, 2025

(30) Foreign Application Priority Data
Mar. 27, 2025 (KR) 10-2025-0039730

(51) Int. Cl. G11C 29/02; G11C 17/16; G11C 17/18; G11C 29/56

(52) U.S. Cl. CPC G11C 29/027; G11C 17/16; G11C 17/18; G11C 29/56016

(57) ABSTRACT

An integrated circuit includes a direct access (DA) pad area configured to generate an input control signal by receiving an external input signal from the outside of the integrated circuit through a plurality of pads, configured to generate an external output signal by receiving an output control signal, and configured to output the external output signal to the outside of the integrated circuit through the plurality of pads, and a fuse array circuit configured to generate fuse data by performing any one of a bootup operation, a rupture operation, a read operation, and a repair operation on a plurality of electronic fuses (E-fuses) based on a power-up signal and a fuse control command and configured to generate the output control signal from the fuse data. The fuse array circuit detects whether the rupture operation is performed based on the input control signal after the start of a direct access operation.

### CROSS-REFERENCE TO RELATED APPLICATION

The present application claims priority under 35 U.S.C. § 119(a) to Korean Patent Application No. 10-2025-0039730, filed in the Korean Intellectual Property Office on Mar. 27, 2025, the entire contents of which application is incorporated herein by reference.

### BACKGROUND

### 1. Technical Field

The present disclosure generally relates to a memory system, and more particularly, a memory system configured for controlling a fuse array circuit through a direct access operation.

### 2. Related Art

Recently, a stack memory system, such as high bandwidth memory (HBM), is used in wide application fields due to its excellent bandwidth. Unlike the existing memory system using a parallel data bus, the stack memory system includes a stack memory device including a base chip and core chips that are connected by through silicon vias (TSVs).

Furthermore, the base chip included in HBM may program various pieces of information through a plurality of electrical fuses (E-fuses). The plurality of E-fuses may be programmed so that the state of the fuse is electrically short-circuited in order for a certain amount of a high current to flow into the material of the fuse by inducing the material of the fuse to be ruptured. In particular, the plurality of E-fuses can be used even after the package assembly of the chip is completed, which is called an anti-fuse method. A manufacturer who manufactures the chip by performing an operation of repairing a failure occurring in the package state prefers the anti-fuse method rather than a fuse cutting method using a laser.

### SUMMARY

In an embodiment, an integrated circuit may include a direct access (DA) pad area configured to generate an input control signal by receiving an external input signal from the outside of the integrated circuit through a plurality of pads, configured to generate an external output signal in response to receiving an output control signal, and configured to output the external output signal to the outside of the integrated circuit through the plurality of pads and a fuse array circuit configured to generate fuse data by performing any one of a bootup operation, a rupture operation, a read operation, and a repair operation on a plurality of electronic fuses (E-fuses) based on a power-up signal and a fuse control command and configured to generate the output control signal from the fuse data. The fuse array circuit detects whether the rupture operation is performed based on the input control signal after the start of a direct access operation.

In an embodiment, an integrated circuit may include a direct access (DA) pad area configured to generate an input control signal by receiving an external input signal from the outside of the integrated circuit through a plurality of pads, configured to generate an external output signal in response to receiving an output control signal, and configured to output the external output signal to the outside of the integrated circuit through the plurality of pads and a fuse array circuit configured to perform a bootup operation of outputting fuse data programmed into a plurality of electronic fuses (E-fuses) based on a power-up signal and configured to perform a rupture operation of programming the fuse data by cutting the plurality of E-fuses based on a fuse control command. The fuse array circuit detects whether the rupture operation is performed based on the input control signal after the start of a direct access operation.

In an embodiment, a memory device may include a first micro bump configured to generate an input control signal by receiving an external input signal from the outside of the memory device, a second micro bump configured to generate an external output signal in response to receiving an output control signal and configured to output the external output signal to the outside of the memory device, and a base chip electrically connected to the first micro bump and the second micro bump, configured to generate fuse data by performing a bootup operation and a rupture operation on a plurality of electronic fuses (E-fuses) based on a power-up signal and a fuse control command, configured to generate the output control signal from the fuse data and to output the output control signal to the second micro bump, and configured to detect whether the rupture operation is performed based on the input control signal received through the first micro bump.

### BRIEF DESCRIPTION OF THE DRAWINGS

FIG. 1 is a block diagram illustrating a construction of a memory system according to an embodiment of the present disclosure.

FIG. 2 is a block diagram illustrating a construction of a base chip according to an embodiment of the present disclosure.

FIG. 3 is a block diagram illustrating a construction of a fuse array circuit according to an embodiment of the present disclosure.

FIG. 4 is a block diagram illustrating a construction of a fuse control circuit according to an embodiment of the present disclosure.

FIG. 5 is a block diagram illustrating a construction of a fuse circuit according to an embodiment of the present disclosure.

FIG. 6 is a block diagram illustrating a construction of a fuse cell array area according to an embodiment of the present disclosure.

FIG. 7 is a block diagram illustrating a construction of a DA pad area according to an embodiment of the present disclosure.

FIG. 8 is a block diagram illustrating a construction of a DA pad area according to another embodiment of the present disclosure.

FIGS. 9 to 13 are diagrams for describing operations of the fuse array circuit according to an embodiment of the present disclosure.

FIG. 14 is a block diagram illustrating a construction of a base chip according to another embodiment of the present disclosure.

### DETAILED DESCRIPTION

In the following description of embodiments, when a parameter is referred to as being “predetermined” or “preset” it may be intended to mean that a value of the parameter is determined in advance when the parameter is used in a process or an algorithm. The value of the parameter may be set when the process or the algorithm starts or may be set during a period in which the process or the algorithm is executed.

In the descriptions of the following embodiments, terms such as “first” and “second,” which are used to distinguish among various components, are not limited by the components. For example, a first component may be referred to as a second component, and vice versa.

When one component is referred to as being “coupled” or “connected” to another component, it should be understood that the components may be directly coupled or connected to each other or coupled or connected to each other through another component interposed therebetween. In contrast, when one component is referred to as being “directly coupled” or “directly connected” to another component, it should be understood that the components are directly coupled or connected to each other without another component interposed therebetween.

A “logic high level” and a “logic low level” are used to describe the logic levels of signals. A signal having a “logic high level” is distinguished from a signal having a “logic low level.” For example, when a signal having a first voltage corresponds to a signal having a “logic high level,” a signal having a second voltage may correspond to a signal having a “logic low level.” According to an embodiment, a “logic high level” may be set to a voltage higher than a “logic low level.” According to an embodiment, the logic levels of signals may be set to different logic levels or opposite logic levels. For example, a signal having a logic high level may be set to have a logic low level in some embodiments, and a signal having a logic low level may be set to have a logic high level in some embodiments.

A “binary bit set” may mean a combination of logic levels of bits included in a signal. When a logic level of each of the bits included in the signal is changed, a binary bit set of the signal may be differently set. For example, when the logic level of each of two bits included in a signal is a “logic low level, a logic low level” when the two bits are included in the signal, a binary bit set of the signal may be set as “00.” When the logic level of each of the two bits included in the signal is a “logic low level, logic high level”, a binary bit set of the signal may be set as “01.”

Hereafter, the present disclosure will be described in more detail through embodiments. The embodiments are only used to exemplify the present disclosure, and the scope of the present disclosure is not limited by the embodiments.

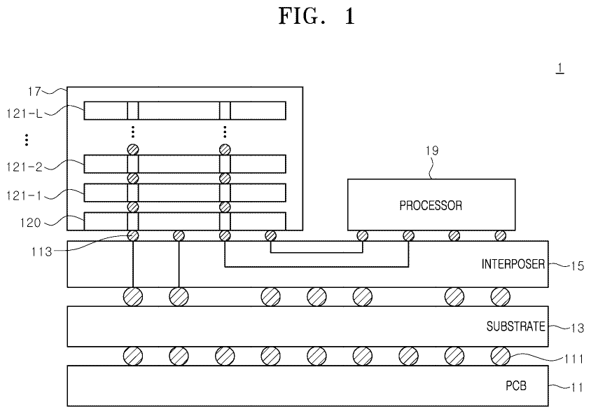

FIG. 1 is a block diagram illustrating a construction of a memory system 1 according to an embodiment of the present disclosure.

As illustrated in FIG. 1, the memory system 1 may include a printed circuit board (PCB) 11, a substrate 13, an interposer 15, a memory device 17, and a processor 19.

The PCB 11 connects several electronic components in order to form an electronic circuit (not illustrated). A copper layer, a solder mask and a silk screen may be formed on the PCB 11. A circuit path that transmits a signal or power may be formed in the copper layer. The solder mask prevents or mitigates damage to the circuit and protects a specific region in which components may be soldered. Furthermore, the silk screen indicates a position or information of an electronic component in the form of characters or symbols printed on a surface of the PCB 11.

The substrate 13 is formed over the PCB 11 through bumps (e.g., 111), and may mechanically support the interposer 15, the memory device 17, and the processor 19. The substrate 13 may be used as an insulator as a material, that is, a physical base for the PCB 11, in general. The material of the substrate 13 include fire retardant 4 (FR4), that is, an insulator made of glass fiber and epoxy resin, ceramics which can withstand a high temperature and is commonly used in a high frequency circuit or a high temperature environment due to its thermal conductivity, and polyimide which is used as a base material for a flexible PCB due to its flexible characteristic.

The interposer 15 is formed over the substrate 13 through bumps, and may include wires that connect electronic components (e.g., the memory device 17 and the processor 19) with unmatched foam factors or pin arrangements. The interposer 15 may convert signals in different interfaces.

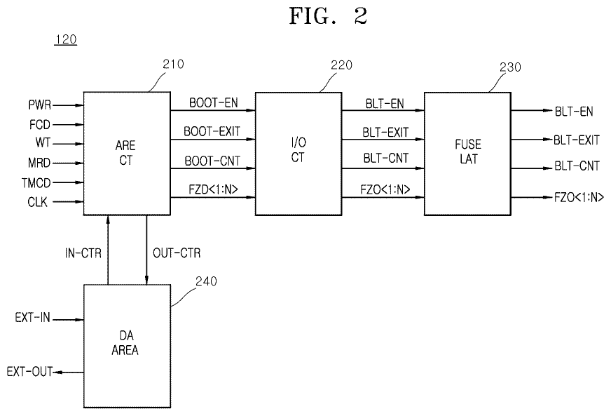

The memory device 17 may be formed over the interposer 15 through micro bumps (e.g., 113). The memory device 17 may store data applied by the processor 19 or output data stored in the memory device 17 to the processor 19, under the control of the processor 19. The memory device 17 may include a base chip 120 and a plurality of core chips 121-1 to 121-L. The plurality of core chips 121-1 to 121-L may be stacked on or over the base chip 120 through micro bumps. The base chip 120 and the plurality of core chips 121-1 to 121-L may be vertically connected through TSVs. The base chip 120 may include a fuse array circuit (ARE CT) (210 in FIG. 2) that is implemented with a plurality of E-fuses. When a power-up operation is completed, the base chip 120 may perform a bootup operation on the fuse array circuit (210 in FIG. 2). When a power-up operation is completed, the base chip 120 may output fuse data (FZD<1:N> in FIG. 2) programmed into the fuse array circuit (210 in FIG. 2). When a power-up operation is completed, the base chip 120 may output a bootup enable signal (BOOT-EN in FIG. 2), a bootup exit signal (BOOT-EXIT in FIG. 2), and a bootup counting signal (BOOT-CNT in FIG. 2) programmed into the fuse array circuit (210 in FIG. 2). The bootup enable signal (BOOT-EN in FIG. 2) may be set as a signal that is enabled during a bootup operation interval. The bootup exit signal (BOOT-EXIT in FIG. 2) may be set as a signal that is enabled when a bootup operation is terminated. The bootup counting signal (BOOT-CNT in FIG. 2) may be set as a signal that is sequentially counted after the start of a bootup operation and that includes location information of a plurality of E-fuses. The base chip 120 may generate the fuse data (FZD<1:N> in FIG. 2) by performing any one of a rupture operation, a read operation, and a repair operation on the fuse array circuit (210 in FIG. 2) based on a fuse control command (FCD in FIG. 2). The base chip 120 may program the fuse data (FZD<1:N> in FIG. 2) by cutting the plurality of E-fuses included in the fuse array circuit (210 in FIG. 2) after the start of a rupture operation based on the fuse control command (FCD in FIG. 2). The base chip 120 may output the fuse data (FZD<1:N> in FIG. 2) generated by programming the plurality of E-fuses included in the fuse array circuit (210 in FIG. 2) after the start of a read operation based on the fuse control command (FCD in FIG. 2). The base chip 120 may detect whether a rupture operation is performed by detecting the fuse data (FZD<1:N> in FIG. 2) after the start of a read operation based on the fuse control command (FCD in FIG. 2). The base chip 120 may output the fuse data (FZD<1:N> in FIG. 2) generated by programming the plurality of E-fuses included in the fuse array circuit (210 in FIG. 2) after the start of a repair operation based on the fuse control command (FCD in FIG. 2). The base chip 120 may program the fuse data (FZD<1:N> in FIG. 2) by cutting a plurality of other E-fuses when the fuse data (FZD<1:N> in FIG. 2) do not have a set logic level after the start of a repair operation based on the fuse control command (FCD in FIG. 2). The base chip 120 may detect whether a rupture operation is performed when the fuse data (FZD<1:N> in FIG. 2) do not have a set logic level based on a signal that is received through a pad after the start of a direct access operation. The base chip 120 may be referred to as, for example, an integrated circuit, a logic chip, a base die, or a semiconductor chip. The plurality of core chips 121-1 to 121-L may each be referred to as, for example, an integrated circuit, a memory chip, a core die, or a semiconductor chip.

The plurality of core chips 121-1 to 121-L may each include a plurality of channel areas that independently operate. The plurality of channel areas may each be assigned a channel that independently operates, and may receive or transmit data. The plurality of channel areas may each include a core area and may receive or transmit data. The number L of plurality of core chips 121-1 to 121-L may be 4, 8, 12, or 16. For example, when each of the core chips 121-1 to 121-12 includes eight channels, each of the core chips 121-1 to 121-4, the core chips 121-5 to 121-8, and the core chips 121-9 to 121-12 may each include 32 channel areas, and may transmit and receive data to and from the processor 19 in a rank unit including 32 channels.

The processor 19 may control an operation of the base chip 120 through wires formed within the interposer 15. The processor 19 may control the base chip 120 so that a command (not illustrated) and signals (not illustrated) that control operations of the plurality of core chips 121-1 to 121-L are output to the plurality of core chips 121-1 to 121-L that performs operations.

FIG. 2 is a block diagram illustrating a construction of the base chip 120 according to an embodiment of the present disclosure. As illustrated in FIG. 2, the base chip 120 may include the fuse array circuit (ARE CT) 210, an input and output circuit (I/O CT) 220, a fuse latch circuit (FUSE LAT) 230, and a direct access (DA) pad area (DA AREA) 240.

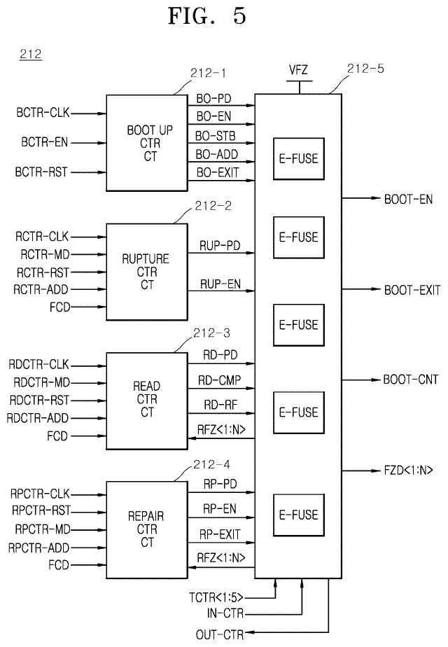

The fuse array circuit 210 may perform any one of a bootup operation, a rupture operation, a read operation, and a repair operation on a plurality of electronic-fuses (E-fuses) (E-FUSE in FIG. 5) based on a power-up signal PWR, the fuse control command FCD, a write command WT, mode data MRD, and a test code signal TMCD in synchronization with a clock signal CLK. The power-up signal PWR may be set as a signal that is enabled when a power-up operation is completed. The power-up operation may be set as an operation in which the voltage level of an internal voltage that is used within the memory device 17 rises based on the level of a source voltage that is supplied from the outside of the memory system 1. The power-up signal PWR may be enabled when the voltage level of the internal voltage rises up to a set voltage level. The fuse control command FCD may be set as a command that is input in order to perform a rupture operation, a read operation, and a repair operation. The fuse control command FCD may be input every set interval (e.g., 5 μsec) after the start of a rupture operation. The set interval may be set as a time interval during which the plurality of E-fuses is cut by a fuse voltage (VFZ in FIG. 5). The write command WT may be set as a command that receives the mode data MRD. The mode data MRD may be set as a signal including address information that selects the plurality of E-fuses after the start of a rupture operation, a read operation, and a repair operation. The test code signal TMCD may be set as a signal including a plurality of bits. The test code signal TMCD may include a plurality of bits that sets a bootup operation, a rupture operation, a read operation, a repair operation, and a direct access operation. The direct access operation may be set as an operation of controlling an operation of the fuse array circuit 210 through the DA pad area 240 and detecting whether a rupture operation is performed on the fuse array circuit 210.

The fuse array circuit 210 may output fuse data FZD<1:N> programmed into the plurality of E-fuses (E-FUSE in FIG. 5) by performing a bootup operation based on the power-up signal PWR that is enabled when a power-up operation is completed. The fuse array circuit 210 may output the bootup enable signal BOOT-EN, the bootup exit signal BOOT-EXIT, and the bootup counting signal BOOT-CNT by performing a bootup operation based on the power-up signal PWR that is enabled when a power-up operation is completed. The bootup enable signal BOOT-EN may be set as a signal that is enabled during a bootup operation interval. The bootup exit signal BOOT-EXIT may be set as a signal that is enabled when a bootup operation is terminated. The bootup counting signal BOOT-CNT may be set as a signal that is sequentially counted after the start of a bootup operation and that includes location information of the plurality of E-fuses. The number N of bits of the fuse data FZD<1:N> may be set as a positive integer greater than 0. The number of bits of the fuse data FZD<1:N> may be set as various numbers of bits according to an embodiment.

The fuse array circuit 210 may program the fuse data FZD<1:N> by cutting the plurality of E-fuses (E-FUSE in FIG. 5) after the start of a rupture operation based on the fuse control command FCD and the test code signal TMCD. When the fuse control command FCD is input and the test code signal TMCD has a logic level combination for a rupture operation, the fuse array circuit 210 may program the fuse data FZD<1:N> by cutting the E-fuse (E-FUSE in FIG. 5) that is selected by the mode data MRD, among the plurality of E-fuses (E-FUSE in FIG. 5). When the fuse control command FCD is input and the test code signal TMCD has a logic level combination for a rupture operation, the fuse array circuit 210 may program the fuse data FZD<1:N> by cutting the E-fuse (E-FUSE in FIG. 5) by applying the fuse voltage (VFZ in FIG. 5) to the E-fuse (E-FUSE in FIG. 5) that is selected among the plurality of E-fuses (E-FUSE in FIG. 5) during a set interval.

The fuse array circuit 210 may output programmed fuse data FZD<1:N> after the start of a read operation based on the fuse control command FCD and the test code signal TMCD. When the fuse control command FCD is input and the test code signal TMCD has a logic level combination for a read operation, the fuse array circuit 210 may detect whether a rupture operation is performed by detecting the logic level of the fuse data FZD<1:N>. For example, after the start of a read operation, when the fuse data FZD<1:N> do not have a preset logic level combination, the fuse array circuit 210 may detect that a rupture operation is not performed. The preset logic level combination may be set as the same logic level combination as the mode data MRD, and may be set as various logic level combinations according to an embodiment.

The fuse array circuit 210 may output the fuse data FZD<1:N> programmed by a rupture operation after the start of a repair operation based on the fuse control command FCD and the test code signal TMCD. When the fuse control command FCD is input and the test code signal TMCD has a logic level combination for a repair operation, the fuse array circuit 210 may perform a rupture operation again by detecting the logic level of the fuse data FZD<1:N>. For example, after the start of a repair operation, when the fuse data FZD<1:N> do not have the same logic level combination as the mode data MRD, the fuse array circuit 210 may program the fuse data FZD<1:N> by cutting another E-fuse (E-FUSE in FIG. 5).

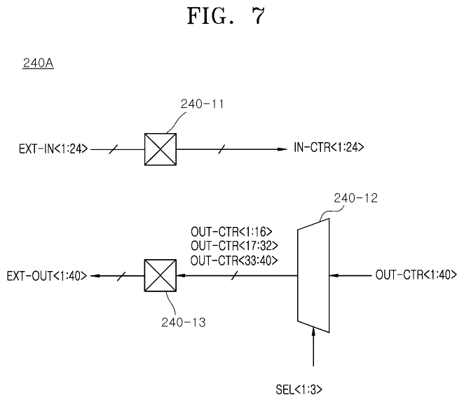

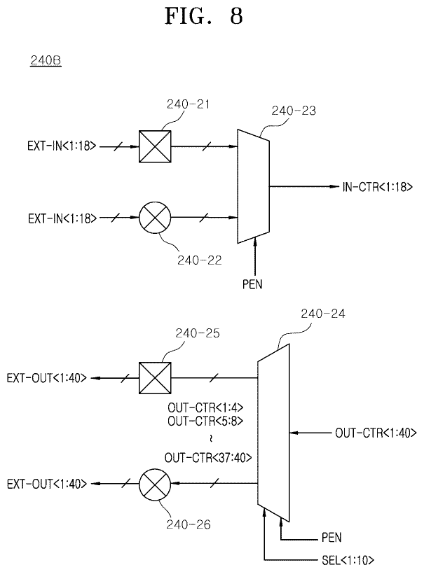

After the start of a direct access operation, the fuse array circuit 210 may output the fuse data FZD<1:N> programmed by a rupture operation as an output control signal OUT-CTR based on the input control signal IN-CTR. The fuse array circuit 210 may output the output control signal OUT-CTR that is generated from the fuse data FZD<1:N> programmed into the E-fuse (E-FUSE in FIG. 5) that is selected among the plurality of E-fuses (E-FUSE in FIG. 5) based on the input control signal IN-CTR. When the output control signal OUT-CTR generated from the fuse data FZD<1:N> after the start of a direct access operation has the same logic level combination as the mode data MRD, the fuse array circuit 210 may detect that a rupture operation is performed on the E-fuse (E-FUSE in FIG. 5). When the output control signal OUT-CTR generated from the fuse data FZD<1:N> after the start of a direct access operation has a logic level combination different from a logic level combination of the mode data MRD, the fuse array circuit 210 may detect that a rupture operation is not performed on the E-fuse (E-FUSE in FIG. 5). The input control signal IN-CTR and the output control signal OUT-CTR may each be set as a signal including a plurality of bits. The number of bits of each of the input control signal IN-CTR and the output control signal OUT-CTR is described below with reference to FIGS. 7 and 8.

The input and output circuit 220 may generate a bootup latch enable signal BLT-EN, a bootup latch exit signal BLT-EXIT, a bootup latch counting signal BLT-CNT, and fuse output data FZO<1:N>, based on the bootup enable signal BOOT-EN, the bootup exit signal BOOT-EXIT, the bootup counting signal BOOT-CNT, and the fuse data FZD<1:N>. The input and output circuit 220 may output the bootup enable signal BOOT-EN as the bootup latch enable signal BLT-EN. The input and output circuit 220 may output the bootup exit signal BOOT-EXIT as the bootup latch exit signal BLT-EXIT. The input and output circuit 220 may output the bootup counting signal BOOT-CNT as the bootup latch counting signal BLT-CNT. The input and output circuit 220 may output the fuse data FZD<1:N> as the fuse output data FZO<1:N>.

The fuse latch circuit 230 may latch the bootup latch enable signal BLT-EN, the bootup latch exit signal BLT-EXIT, the bootup latch counting signal BLT-CNT, and the fuse output data FZO<1:N>. The fuse latch circuit 230 may output the bootup latch enable signal BLT-EN, the bootup latch exit signal BLT-EXIT, and the bootup latch counting signal BLT-CNT, which are latched, to the outside of the base chip 120. The fuse latch circuit 230 may output the bootup latch enable signal BLT-EN, the bootup latch exit signal BLT-EXIT, and the bootup latch counting signal BLT-CNT, which are latched, to the processor 19. The fuse latch circuit 230 may output the bootup latch enable signal BLT-EN, the bootup latch exit signal BLT-EXIT, and the bootup latch counting signal BLT-CNT, which are latched, to a test device (not illustrated). The fuse latch circuit 230 may control various test modes based on latched fuse output data FZO<1:N>. For example, the fuse latch circuit 230 may control a test mode in which a chip ID that selects the plurality of core chips 121-1 to 121-L is changed based on latched fuse output data FZO<1:N>. The fuse latch circuit 230 may control various test modes in which a delay quantity by which the signals of the plurality of core chips 121-1 to 121-L are delayed is changed based on latched fuse output data FZO<1:N>. The fuse latch circuit 230 may control a test mode in which a memory cell of the plurality of core chips 121-1 to 121-L is substituted based on latched fuse output data FZO<1:N>.

The DA pad area 240 may include a plurality of pads (240-11 and 240-13 in FIG. 7 and 240-21 and 240-25 in FIG. 8). The DA pad area 240 may generate the input control signal IN-CTR by receiving an external input signal EXT-IN from the outside of the base chip 120 through the plurality of pads. The DA pad area 240 may generate an external output signal EXT-OUT by receiving the output control signal OUT-CTR through the plurality of pads. The DA pad area 240 may output the external output signal EXT-OUT to the outside of the base chip 120 through the plurality of pads.

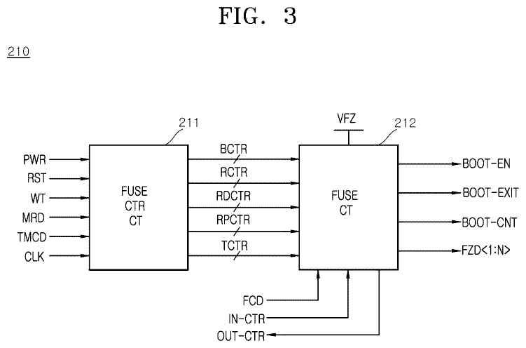

FIG. 3 is a block diagram illustrating a construction of the fuse array circuit 210 according to an embodiment of the present disclosure. As illustrated in FIG. 3, the fuse array circuit 210 may include a fuse control circuit (FUSE CTR CT) 211 and a fuse circuit (FUSE CT) 212.

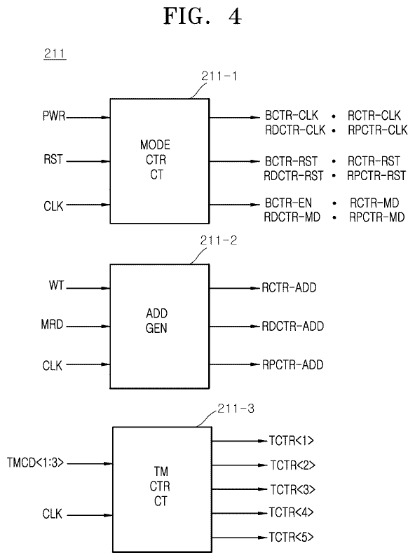

The fuse control circuit 211 may generate a bootup control signal BCTR, a rupture control signal RCTR, a read control signal RDCTR, a repair control signal RPCTR, and a transfer control signal TCTR, based on the power-up signal PWR, a reset signal RST, the write command WT, the mode data MRD, and the test code signal TMCD in synchronization with the clock signal CLK. The bootup control signal BCTR may be set as a signal including a bootup control clock signal (BCTR-CLK in FIG. 4), a bootup control reset signal (BCTR-RST in FIG. 4), and a bootup control enable signal (BCTR-EN in FIG. 4). The rupture control signal RCTR may be set as a signal including a rupture control clock signal (RCTR-CLK in FIG. 4), a rupture control reset signal (RCTR-RST in FIG. 4), a rupture control mode signal (RCTR-MD in FIG. 4), and a rupture control address (RCTR-ADD in FIG. 4). The read control signal RDCTR may be set as a signal including a read control clock signal (RDCTR-CLK in FIG. 4), a read control reset signal (RDCTR-RST in FIG. 4), a read control mode signal (RDCTR-MD in FIG. 4), and a read control address (RDCTR-ADD in FIG. 4). The repair control signal RPCTR may be set as a signal including a repair control clock signal (RPCTR-CLK in FIG. 4), a repair control reset signal (RPCTR-RST in FIG. 4), a repair control mode signal (RPCTR-MD in FIG. 4), and a repair control address (RPCTR-ADD in FIG. 4). The transfer control signal TCTR may be set as a signal including a first transfer control signal (TCTR<1> in FIG. 4), a second transfer control signal (TCTR<2> in FIG. 4), a third transfer control signal (TCTR<3> in FIG. 4), a fourth transfer control signal (TCTR<4> in FIG. 4), and a fifth transfer control signal (TCTR<5> in FIG. 4). The clock signal CLK may be set as a common clock signal that is periodically toggled.

The fuse circuit 212 may output the fuse data FZD<1:N> programmed into the plurality of E-fuses (E-FUSE in FIG. 5) by performing a bootup operation based on the transfer control signal TCTR and the bootup control signal BCTR. The fuse circuit 212 may generate the bootup enable signal BOOT-EN that is enabled during a bootup operation interval by performing a bootup operation based on the fuse control command FCD, the transfer control signal TCTR, and the bootup control signal BCTR. The fuse circuit 212 may generate the bootup exit signal BOOT-EXIT that is enabled when a bootup operation is terminated based on the fuse control command FCD, the transfer control signal TCTR, and the bootup control signal BCTR. The fuse circuit 212 may generate the bootup counting signal BOOT-CNT that is sequentially counted after the start of a bootup operation based on the fuse control command FCD, the transfer control signal TCTR, and the bootup control signal BCTR.

The fuse circuit 212 may program the fuse data FZD<1:N> by cutting the plurality of E-fuses (E-FUSE in FIG. 5) by performing a rupture operation based on the fuse control command FCD, the transfer control signal TCTR, and the rupture control signal RCTR. The fuse circuit 212 may program the fuse data FZD<1:N> by cutting the E-fuse (E-FUSE in FIG. 5) that is selected among the plurality of E-fuses (E-FUSE in FIG. 5) based on the fuse control command FCD, the transfer control signal TCTR, and the rupture control signal RCTR. The fuse circuit 212 may program the fuse data FZD<1:N> by cutting the E-fuse (E-FUSE in FIG. 5) by applying the fuse voltage VFZ to the E-fuse (E-FUSE in FIG. 5) that is selected among the plurality of E-fuses (E-FUSE in FIG. 5) based on the fuse control command FCD, the transfer control signal TCTR, and the rupture control signal RCTR.

The fuse circuit 212 may output programmed fuse data FZD<1:N> by performing a read operation based on the fuse control command FCD, the transfer control signal TCTR, and the read control signal RDCTR. The fuse circuit 212 may output the fuse data FZD<1:N> programmed into the E-fuse (E-FUSE in FIG. 5) that is selected among the plurality of E-fuses (E-FUSE in FIG. 5) by performing a read operation based on the fuse control command FCD, the transfer control signal TCTR, and the read control signal RDCTR. When the fuse data FZD<1:N> have a preset logic level combination, the fuse circuit 212 may detect that a rupture operation is performed. When the fuse data FZD<1:N> do not have a preset logic level combination, the fuse circuit 212 may detect that a rupture operation is not performed.

The fuse circuit 212 may output programmed fuse data FZD<1:N> by performing a repair operation based on the fuse control command FCD, the transfer control signal TCTR, and the repair control signal RPCTR. The fuse circuit 212 may output the fuse data FZD<1:N> programmed into the E-fuse (E-FUSE in FIG. 5) that is selected among the plurality of E-fuses (E-FUSE in FIG. 5) by performing a repair operation based on the fuse control command FCD, the transfer control signal TCTR, and the repair control signal RPCTR. When the fuse data FZD<1:N> do not have the same logic level combination as the mode data MRD, the fuse circuit 212 may program the fuse data FZD<1:N> again by cutting another E-fuse (E-FUSE in FIG. 5).

The fuse circuit 212 may output the fuse data FZD<1:N> programmed by a rupture operation as the output control signal OUT-CTR based on the transfer control signal TCTR and the input control signal IN-CTR. The fuse circuit 212 may output the fuse data FZD<1:N> programmed into the E-fuse (E-FUSE in FIG. 5) that is selected among the plurality of E-fuses (E-FUSE in FIG. 5) as the output control signal OUT-CTR based on the transfer control signal TCTR and the input control signal IN-CTR.

FIG. 4 is a block diagram illustrating a construction of the fuse control circuit 211 according to an embodiment of the present disclosure. As illustrated in FIG. 4, the fuse control circuit 211 may include a mode control circuit (MODE CTR CT) 211-1, an address generation circuit (ADD GEN) 211-2, and a test control circuit (TM CTR CT) 211-3.

The mode control circuit 211-1 may generate the bootup control clock signal BCTR-CLK, the rupture control clock signal RCTR-CLK, the read control clock signal RDCTR-CLK, and the repair control clock signal RPCTR-CLK based on the power-up signal PWR in synchronization with the clock signal CLK. The mode control circuit 211-1 may generate the bootup control clock signal BCTR-CLK, the rupture control clock signal RCTR-CLK, the read control clock signal RDCTR-CLK, and the repair control clock signal RPCTR-CLK each of which is periodically toggled when the power-up signal PWR is enabled, in synchronization with the clock signal CLK.

The mode control circuit 211-1 may generate the bootup control reset signal BCTR-RST, the rupture control reset signal RCTR-RST, the read control reset signal RDCTR-RST, and the repair control reset signal RPCTR-RST based on the reset signal RST in synchronization with the clock signal CLK. The mode control circuit 211-1 may generate the bootup control reset signal BCTR-RST, the rupture control reset signal RCTR-RST, the read control reset signal RDCTR-RST, and the repair control reset signal RPCTR-RST that are enabled when the reset signal RST is enabled, in synchronization with the clock signal CLK. The reset signal RST may be set as a signal that is enabled in order to initialize a bootup operation, a rupture operation, a read operation, and a repair operation.

The mode control circuit 211-1 may generate the bootup control enable signal BCTR-EN, the rupture control mode signal RCTR-MD, the read control mode signal RDCTR-MD, and the repair control mode signal RPCTR-MD based on the power-up signal PWR in synchronization with the clock signal CLK. The bootup control enable signal BCTR-EN may be set as a signal that is enabled after the start of a bootup operation. The rupture control mode signal RCTR-MD may be set as a signal that is enabled in order to rupture one E-fuse after the start of a rupture operation. The read control mode signal RDCTR-MD may be set as a signal that is enabled in order to output one programmed fuse data FZD<1:N>. The repair control mode signal RPCTR-MD may be set as a signal that is enabled in order to rupture the E-fuse again.

The address generation circuit 211-2 may generate the rupture control address RCTR-ADD, the read address RDCTR-ADD, and the repair address RPCTR_ADD based on the write command WT and the mode data MRD in synchronization with the clock signal CLK. The address generation circuit 211-2 may generate the rupture control address RCTR-ADD based on the mode data MRD when the write command WT is enabled in synchronization with the clock signal CLK after the start of a rupture operation. The address generation circuit 211-2 may generate the read address RDCTR-ADD based on the mode data MRD when the write command WT is enabled in synchronization with the clock signal CLK after the start of a read operation. The address generation circuit 211-2 may generate the repair address RPCTR_ADD based on the mode data MRD when the write command WT is enabled in synchronization with the clock signal CLK after the start of a repair operation.

The test control circuit 211-3 may generate the first transfer control signal TCTR<1>, the second transfer control signal TCTR<2>, the third transfer control signal TCTR<3>, the fourth transfer control signal TCTR<4>, and the fifth transfer control signal TCTR<5> based on the first to third test code signals TMCD<1:3> in synchronization with the clock signal CLK. The test control circuit 211-3 may generate the first transfer control signal TCTR<1> that is enabled when the first to third test code signals TMCD<1:3> have a logic level combination that performs a bootup operation in synchronization with the clock signal CLK. The test control circuit 211-3 may generate the second transfer control signal TCTR<2> that is enabled when the first to third test code signals TMCD<1:3>have a logic level combination that performs a rupture operation in synchronization with the clock signal CLK. The test control circuit 211-3 may generate the third transfer control signal TCTR<3> that is enabled when the first to third test code signals TMCD<1:3> have a logic level combination that performs a read operation in synchronization with the clock signal CLK. The test control circuit 211-3 may generate the fourth transfer control signal TCTR<4> that is enabled when the first to third test code signals TMCD<1:3> have a logic level combination that performs a rupture operation in synchronization with the clock signal CLK. The test control circuit 211-3 may generate the fifth transfer control signal TCTR<5> that is enabled when the first to third test code signals TMCD<1:3> have a logic level combination that performs a direct access operation in synchronization with the clock signal CLK.

FIG. 5 is a block diagram illustrating a construction of the fuse circuit 212 according to an embodiment of the present disclosure. As illustrated in FIG. 5, the fuse circuit 212 may include a bootup control circuit (BOOT UP CTR CT) 212-1, a rupture control circuit (RUPTURE CTR CT) 212-2, a read control circuit (READ CTR CT) 212-3, a repair control circuit (REPAIR CTR CT) 212-4, and a fuse cell array area 212-5.

The bootup control circuit 212-1 may generate a bootup internal-driving signal BO-PD, a bootup internal-enable signal BO-EN, a bootup internal-standby signal BO-STB, a bootup internal-address BO-ADD, and a bootup internal-exit signal BO-EXIT that perform a bootup operation based on the bootup control clock signal BCTR-CLK, the bootup control enable signal BCTR-EN, and the bootup control reset signal BCTR-RST. The bootup internal-driving signal BO-PD may include a plurality of bits so that the bootup internal-driving signal BO-PD includes various pieces of information that perform a bootup operation. The bootup internal-enable signal BO-EN may be set as a signal that is enabled when a bootup operation is entered. The bootup internal-standby signal BO-STB may be set as a signal that is enabled when a bootup operation is terminated. The bootup internal-address BO-ADD may be set as a signal that is sequentially counted in order to sequentially select the E-fuses after the start of a bootup operation. The bootup internal-exit signal BO-EXIT may be set as a signal that is enabled from the time when a bootup operation begins to the time when the bootup operation is terminated. The bootup control circuit 212-1 may generate various signals that control a bootup operation.

The rupture control circuit 212-2 may generate a rupture internal-driving signal RUP-PD and a rupture internal-enable signal RUP-EN, based on the rupture control clock signal RCTR-CLK, the rupture control mode signal RCTR-MD, the rupture control reset signal RCTR-RST, the rupture control address RCTR-ADD, and the fuse control command FCD. The rupture internal-driving signal RUP-PD may include a plurality of bits so that the rupture internal-driving signal RUP-PD includes various pieces of information that perform a rupture operation and the rupture control address RCTR-ADD that selects the E-fuse. The rupture internal-enable signal RUP-EN may be set as a signal that is enabled from the time when a rupture operation begins to the time when the rupture operation is terminated. The rupture control circuit 212-2 may generate various signals that control a rupture operation.

The read control circuit 212-3 may generate a read internal-driving signal RD-PD, a read internal-comparison signal RD-CMP, and a read internal-flag signal RD-RF, based on the read control clock signal RDCTR-CLK, the read control mode signal RDCTR-MD, the read control reset signal RDCTR-RST, the read control address RDCTR-ADD, the fuse control command FCD, and a read fuse signal RFZ<1:N>. When the read fuse signal RFZ<1:N> does not have a preset logic level combination, the read control circuit 212-3 may detect that a rupture operation is not performed. The read control circuit 212-3 may generate various signals that control a read operation. The read fuse signal RFZ<1:N> may be set as a signal that is generated from the fuse data FZD<1:N> after the start of a read operation. The read internal-driving signal RD-PD may include a plurality of bits so that the read internal-driving signal RD-PD includes various pieces of information that perform a read operation and the read control address RDCTR-ADD that selects the E-fuse. The read internal-comparison signal RD-CMP may be set as a signal that is enabled when the read fuse signal RFZ<1:N> has a preset logic level combination. When the read internal-comparison signal RD-CMP is enabled, the read control circuit 212-3 may detect that a rupture operation is performed. The read internal-flag signal RD-RF may be set as a signal that is enabled when a read operation is performed.

The repair control circuit 212-4 may generate a repair internal-driving signal RP-PD, a repair internal-enable signal RP-EN, and a repair internal-exit signal RP-EXIT, based on the repair control clock signal RPCTR-CLK, the repair control mode signal RPCTR-MD, the repair control reset signal RPCTR-RST, the repair control address RPCTR-ADD, the fuse control command FCD, and the read fuse signal RFZ<1:N>. When the read fuse signal RFZ<1:N> does not have a preset logic level combination, the repair control circuit 212-4 may control the fuse cell array area 212-5 so that a rupture operation is performed again. The repair internal-driving signal RP-PD may include a plurality of bits so that the repair internal-driving signal RP-PD includes various pieces of information that perform a repair operation and the repair control address RPCTR-ADD that selects the E-fuse. The repair internal-enable signal RP-EN may be set as a signal that is enabled from the time when a repair operation begins to the time when the repair operation is terminated. The repair internal-exit signal RP-EXIT may be set as a signal that is enabled when a repair operation is terminated. The repair control circuit 212-4 may generate various signals that control a repair operation.

The fuse cell array area 212-5 may include the plurality of E-fuses (E-FUSEs). When the first transfer control signal TCTR<1> is enabled, the fuse cell array area 212-5 may generate the bootup enable signal BOOT-EN, the bootup exit signal BOOT-EXIT, the bootup counting signal BOOT-CNT, and the fuse data FZD<1:N> by performing a bootup operation based on the bootup internal-driving signal BO-PD, the bootup internal-enable signal BO-EN, the bootup internal-standby signal BO-STB, the bootup internal-address BO-ADD and the bootup internal-exit signal BO-EXIT. The fuse cell array area 212-5 may generate the bootup enable signal BOOT-EN that is enabled from a time point at which the bootup internal-enable signal BO-EN is enabled to a time point at which the bootup internal-standby signal BO-STB is enabled. The fuse cell array area 212-5 may generate the bootup counting signal BOOT-CNT from the bootup internal-address BO-ADD. The fuse cell array area 212-5 may generate the bootup exit signal BOOT-EXIT from the bootup internal-exit signal BO-EXIT. The fuse cell array area 212-5 may output the fuse data FZD<1:N> programmed into the E-fuse selected among the plurality of E-fuses based on the bootup internal-driving signal BO-PD and the bootup internal-address BO-ADD.

When the second transfer control signal TCTR<2> is enabled, the fuse cell array area 212-5 may perform a rupture operation by applying the fuse voltage VFZ to the E-fuse selected among the plurality of E-fuses based on the rupture internal-driving signal RUP-PD and the rupture internal-enable signal RUP-EN.

When the third transfer control signal TCTR<3> is enabled, the fuse cell array area 212-5 may generate the read fuse signal RFZ<1:N> from the fuse data FZD<1:N> programmed into the E-fuse selected among the plurality of E-fuses, based on the read internal-driving signal RD-PD, the read internal-comparison signal RD-CMP, and the read internal-flag signal RD-RF.

When the fourth transfer control signal TCTR<4> is enabled, the fuse cell array area 212-5 may generate the read fuse signal RFZ<1:N> from the fuse data FZD<1:N> programmed into the E-fuse selected among the plurality of E-fuses based on the repair internal-driving signal RP-PD, the repair internal-enable signal RP-EN, and the repair internal-exit signal RP-EXIT.

When the fifth transfer control signal TCTR<5> is enabled, the fuse cell array area 212-5 may output the fuse data FZD<1:N> programmed by a rupture operation as the output control signal OUT-CTR based on the input control signal IN-CTR. The fuse cell array area 212-5 may output the output control signal OUT-CTR that is generated from the fuse data FZD<1:N> programmed into the E-fuse selected among the plurality of E-fuses based on the input control signal IN-CTR.

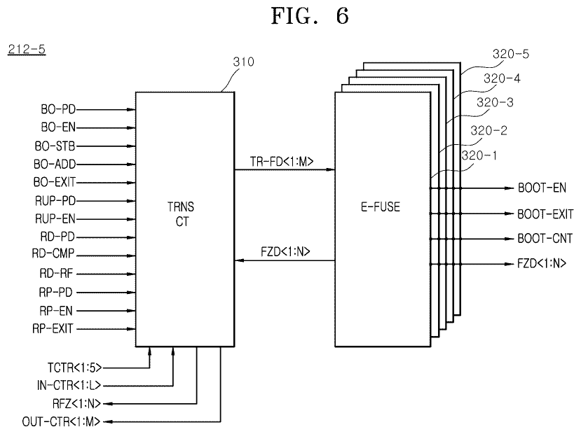

FIG. 6 is a block diagram illustrating a construction of the fuse cell array area 212-5 according to an embodiment of the present disclosure. As illustrated in FIG. 6, the fuse cell array area 212-5 may include a transfer circuit (TRNS CT) 310, a first fuse area (E-FUSE) 320-1, a second fuse area (E-FUSE) 320-2, a third fuse area (E-FUSE) 320-3, a fourth fuse area (E-FUSE) 320-4, and a fifth fuse area (E-FUSE) 320-5.

When the first transfer control signal TCTR<1> is enabled, the transfer circuit 310 may output the bootup internal-driving signal BO-PD, the bootup internal-enable signal BO-EN, the bootup internal-standby signal BO-STB, the bootup internal-address BO-ADD, and the bootup internal-exit signal BO-EXIT as various bits of transfer fuse data TR-FD<1:M>. When the second transfer control signal TCTR<2> is enabled, the transfer circuit 310 may output the rupture internal-driving signal RUP-PD and the rupture internal-enable signal RUP-EN as various bits of the transfer fuse data TR-FD<1:M>.

When the third transfer control signal TCTR<3> is enabled, the transfer circuit 310 may output the read internal-driving signal RD-PD, the read internal-comparison signal RD-CMP, and the read internal-flag signal RD-RF as various bits of the transfer fuse data TR-FD<1:M>.

When the fourth transfer control signal TCTR<4> is enabled, the transfer circuit 310 may output the repair internal-driving signal RP-PD, the repair internal-enable signal RP-EN, and the repair internal-exit signal RP-EXIT as various bits of the transfer fuse data TR-FD<1:M>.

When the fifth transfer control signal TCTR<5> is enabled, the transfer circuit 310 may output the first to L-th bits IN-CTR<1:L> of the input control signal as various bits of the transfer fuse data TR-FD<1:M>. When the fifth transfer control signal TCTR<5> is enabled, the transfer circuit 310 may output the fuse data FZD<1:N> as various bits of the output control signal OUT-CTR<1:M>.

The transfer circuit 310 may output the fuse data FZD<1:N> as the read fuse signal RFZ<1:N>. After the start of a read operation and a repair operation, the transfer circuit 310 may output the fuse data FZD<1:N> as the read fuse signal RFZ<1:N>.

After the start of a bootup operation, the first to fifth fuse areas 320-1 to 320-5 may generate the bootup enable signal BOOT-EN, the bootup exit signal BOOT-EXIT, the bootup counting signal BOOT-CNT, and the fuse data FZD<1:N> based on the first to M-th bits TR-FD<1:M> of the transfer fuse data. The first to fifth fuse areas 320-1 to 320-5 may output the fuse data FZD<1:N> programmed into the E-fuse selected among the plurality of E-fuses based on the first to M-th bits TR-FD<1:M> of the transfer fuse data.

After the start of a rupture operation, the first to fifth fuse areas 320-1 to 320-5 may perform a rupture operation by applying the fuse voltage VFZ to the E-fuse selected among the plurality of E-fuses based on the first to M-th bits TR-FD<1:M> of the transfer fuse data. After the start of a rupture operation, the first to fifth fuse areas 320-1 to 320-5 may program the fuse data FZD<1:N> as the E-fuse selected among the plurality of E-fuses is cut.

After the start of a read operation, the first to fifth fuse areas 320-1 to 320-5 may output the fuse data FZD<1:N> programmed into the E-fuse selected among the plurality of E-fuses based on the first to M-th bits TR-FD<1:M> of the transfer fuse data.

After the start of a repair operation, the first to fifth fuse areas 320-1 to 320-5 may output the fuse data FZD<1:N> programmed into the E-fuse selected among the plurality of E-fuses based on the first to M-th bits TR-FD<1:M> of the transfer fuse data. After the start of a repair operation, when the read fuse signal RFZ<1:N> does not have a preset logic level combination, the first to fifth fuse areas 320-1 to 320-5 may perform a rupture operation again by applying the fuse voltage VFZ to another E-fuse, among the plurality of E-fuses, based on the first to M-th bits TR-FD<1:M> of the transfer fuse data. After the start of a repair operation, the first to fifth fuse areas 320-1 to 320-5 may program the fuse data FZD<1:N> again as another E-fuse, among the plurality of E-fuses, is cut.

After the start of a direct access operation, the first to fifth fuse areas 320-1 to 320-5 may output the fuse data FZD<1:N> programmed into the E-fuse selected among the plurality of E-fuses based on the first to M-th bits TR-FD<1:M> of the transfer fuse data.

The first to fifth fuse areas 320-1 to 320-5 illustrated in FIG. 6 have been implemented with five fuse areas, but may be implemented with various numbers of fuse areas according to an embodiment so that a bootup operation, a rupture operation, a read operation, a repair operation, and a direct access operation can be performed.

FIG. 7 is a block diagram illustrating a construction of the DA pad area 240 according to an embodiment of the present disclosure. As illustrated in FIG. 7, a DA pad area 240A may include the first pad 240-11, a multiplexer 240-12, and the second pad 240-13.

The first pad 240-11 may generate the first to twenty-fourth bits IN-CTR<1:24> of the input control signal by receiving the first to twenty-fourth bits EXT-IN<1:24> of the external input signal. The first pad 240-11 has been illustrated as being one pad, but may be implemented with 24 pads, that is, the number of first to twenty-fourth bits EXT-IN<1:24> of the external input signal.

The multiplexer 240-12 may sequentially output the first to fortieth bits OUT-CTR<1:40> of the output control signal by the first to third bits SEL<1:3> of a selection signal that are sequentially enabled. When the first bit SEL<1> of the selection signal is enabled, the multiplexer 240-12 may receive and output the first to sixteenth bits OUT-CTR<1:16> of the output control signal. When the second bit SEL<2> of the selection signal is enabled, the multiplexer 240-12 may receive and output the seventeenth to thirty-second bits OUT-CTR<17:32> of the output control signal. When the third bit SEL<3> of the selection signal is enabled, the multiplexer 240-12 may receive and output the thirty-third to fortieth bits OUT-CTR<33:40> of the output control signal. The multiplexer 240-12 has been illustrated as being one multiplexer, but may be implemented with 16 multiplexers, that is, the number of first to sixteenth bits OUT-CTR<1:16> of the output control signal that are output at a time.

The second pad 240-13 may sequentially output the first to fortieth bits OUT-CTR<1:40> of the output control signal. When the first to sixteenth bits OUT-CTR<1:16> of the output control signal are output by the multiplexer 240-12, the second pad 240-13 may output the first to sixteenth bits OUT-CTR<1:16> of the output control signal as the first to sixteenth bits EXT-OUT<1:16> of the external output signal. When the seventeenth to thirty-second bits OUT-CTR<17:32> of the output control signal are output by the multiplexer 240-12, the second pad 240-13 may output the seventeenth to thirty-second bits OUT-CTR<17:32> of the output control signal as the seventeenth to thirty-second bits EXT-OUT<17:32> of the external output signal. When the thirty-third to fortieth bits OUT-CTR<33:40> of the output control signal are output by the multiplexer 240-12, the second pad 240-13 may output the thirty-third to fortieth bits OUT-CTR<33:40> of the output control signal as the thirty-third to fortieth bits EXT-OUT<33:40> of the external output signal. The second pad 240-13 has been illustrated as being one pad, but may be implemented with 16 pads, that is, the number of first to sixteenth bits OUT-CTR<1:16> of the output control signal that are output at a time.

The DA pad area 240A illustrated in FIG. 7 may be implemented with 24 first pads 240-11 that receive the first to twenty-fourth bits EXT-IN<1:24> of the external input signal and 16 second pads 240-13 according to the first to sixteenth bits OUT-CTR<1:16> of the output control signal, the seventeenth to thirty-second bits OUT-CTR<17:32> of the output control signal, and the thirty-third to fortieth bits OUT-CTR<33:40> of the output control signal, which are sequentially output. That is, the DA pad area 240A may be implemented with 40 pads.

FIG. 8 is a block diagram illustrating a construction of the DA pad area 240 according to another embodiment of the present disclosure. As illustrated in FIG. 8, a DA pad area 240B may include the first pad 240-21, a first micro bump 240-22, a first multiplexer 240-23, a second multiplexer 240-24, the second pad 240-25, and a second micro bump 240-26.

The first pad 240-21 may receive and output the first to eighteenth bits EXT-IN<1:18> of the external input signal. The first pad 240-21 has been illustrated as being one pad, but may be implemented with 18 pads, that is, the number of first to eighteenth bits EXT-IN<1:18> of the external input signal.

The first micro bump 240-22 may receive and output the first to eighteenth bits EXT-IN<1:18> of the external input signal. The first micro bump 240-22 has been illustrated as being one micro bump, but may be implemented with 18 micro bumps, that is, the number of first to eighteenth bits EXT-IN<1:18> of the external input signal.

The first multiplexer 240-23 may generate the first to eighteenth bits IN-CTR<1:18> of the input control signal by receiving the first to eighteenth bits EXT-IN<1:18> of the external input signal from any one of the first pad 240-21 and the first micro bump 240-22 by the pad enable signal PEN. When the pad enable signal PEN is enabled, the first multiplexer 240-23 may generate the first to eighteenth bits IN-CTR<1:18> of the input control signal by receiving the first to eighteenth bits EXT-IN<1:18> of the external input signal from the first pad 240-21. When the pad enable signal PEN is disabled, the first multiplexer 240-23 may generate the first to eighteenth bits IN-CTR<1:18> of the input control signal by receiving the first to eighteenth bits EXT-IN<1:18> of the external input signal from the first micro bump 240-22. The pad enable signal PEN may be set as a signal that is enabled in an operation of receiving the first to eighteenth bits EXT-IN<1:18> of the external input signal from the pad.

The second multiplexer 240-24 may sequentially output the first to fortieth bits OUT-CTR<1:40> of the output control signal by the pad enable signal PEN and the first to tenth bits SEL<1:10> of the selection signal that are sequentially enabled. When the pad enable signal PEN is enabled and the first bit SEL<1> of the selection signal is enabled, the second multiplexer 240-24 may output the first to fourth bits OUT-CTR<1:4> of the output control signal to the second pad 240-25. When the pad enable signal PEN is disabled and the first bit SEL<1> of the selection signal is enabled, the second multiplexer 240-24 may output the first to fourth bits OUT-CTR<1:4> of the output control signal to the second micro bump 240-26. When the pad enable signal PEN is enabled and the tenth bit SEL<10> of the selection signal is enabled, the second multiplexer 240-24 may output the thirty-seventh to fortieth bits OUT-CTR<37:40> of the output control signal to the second pad 240-25. When the pad enable signal PEN is disabled and the tenth bit SEL<10> of the selection signal is enabled, the second multiplexer 240-24 may output the thirty-seventh to fortieth bits OUT-CTR<37:40> of the output control signal to the second micro bump 240-26.

The second pad 240-25 may sequentially output the first to fortieth bits OUT-CTR<1:40> of the output control signal. When the first to fourth bits OUT-CTR<1:4> of the output control signal are output by the multiplexer 240-24, the second pad 240-25 may output the first to fourth bits OUT-CTR<1:4> of the output control signal as the first to fourth bits EXT-OUT<1:4> of the external output signal. When thirty-seventh to fortieth bits OUT-CTR<37:40> of the output control signal are output by the multiplexer 240-24, the second pad 240-25 may output the thirty-seventh to fortieth bits OUT-CTR<37:40> of the output control signal as the thirty-seventh to fortieth bits EXT-OUT<37:40> of the external output signal. The second pad 240-13 has been illustrated as being one pad, but may be implemented with 4 pads, that is, the number of first to fourth bits OUT-CTR<1:4> of the output control signal that are output at a time. As used herein, the tilde “~” indicates a range of components.

The second micro bump 240-26 may sequentially output the first to fortieth bits OUT-CTR<1:40> of the output control signal. When the first to fourth bits OUT-CTR<1:4> of the output control signal are output by the multiplexer 240-24, the second micro bump 240-26 may output the first to fourth bits OUT-CTR<1:4> of the output control signal as the first to fourth bits EXT-OUT<1:4> of the external output signal. When the thirty-seventh to fortieth bits OUT-CTR<37:40> of the output control signal are output by the multiplexer 240-24, the second micro bump 240-26 may output the thirty-seventh to fortieth bits OUT-CTR<37:40> of the output control signal as the thirty-seventh to fortieth bits EXT-OUT<37:40> of the external output signal. The second micro bump 240-26 has been illustrated as being one micro bump, but may be implemented with 4 micro bumps, that is, the number of first to fourth bits OUT-CTR<1:4> of the output control signal that are output at a time.

The DA pad area 240B illustrated in FIG. 8 may be implemented with 18 first pads 240-21 and 18 first micro bumps 240-22 that receive the first to eighteenth bits EXT-IN<1:18> of the external input signal and 4 second pads 240-25 and 4 second micro bumps 240-26 according to the first to fourth bits OUT-CTR<1:40> of the output control signal that are sequentially output every 4 bits. That is, the DA pad area 240B may be implemented with 22 pads and 22 micro bumps.

The first micro bump 240-22 and the second micro bump 240-26 illustrated in FIG. 8 may be disposed under the base chip 120 and implemented with small micro bumps that are connected to the wires of the interposer 15.

As described above, the base chip 120 of the memory system 1 according to an embodiment of the present disclosure can efficiently control an operation of the fuse array circuit by controlling the fuse array circuit through a direct access operation or performing any one of a bootup operation, a rupture operation, a read operation, and a repair operation on the fuse array circuit based on the fuse control command after a power-up operation is completed. After the start of a direct access operation, the base chip 120 of the memory system 1 may detect whether a rupture operation is performed on the fuse array circuit by applying a signal that controls an operation of the fuse array through the pad and then receiving the fuse data through the pad.

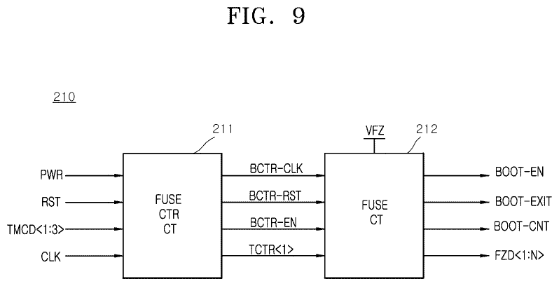

FIG. 9 is a diagram for describing a bootup operation of the fuse array circuit 210 according to an embodiment of the present disclosure.

The fuse control circuit 211 generates the bootup control clock signal BCTR-CLK, the bootup control reset signal BCTR-RST, and the bootup control enable signal BCTR-EN, based on the power-up signal PWR in synchronization with the clock signal CLK. The fuse control circuit 211 generates the first transfer control signal TCTR<1> that is enabled when the first to third test code signals TMCD<1:3> have a logic level combination for a bootup operation in synchronization with the clock signal CLK.

When the first transfer control signal TCTR<1> is enabled, the fuse circuit 212 outputs the fuse data FZD<1:N> programmed into the plurality of E-fuses (E-FUSE in FIG. 5) by performing a bootup operation based on the bootup control clock signal BCTR-CLK, the bootup control reset signal BCTR-RST, and the bootup control enable signal BCTR-EN. When the first transfer control signal TCTR<1> is enabled, the fuse circuit 212 generates the bootup enable signal BOOT-EN that is enabled during a bootup operation interval by performing a bootup operation based on the bootup control clock signal BCTR-CLK, the bootup control reset signal BCTR-RST, and the bootup control enable signal BCTR-EN. When the first transfer control signal TCTR<1> is enabled, the fuse circuit 212 generates the bootup exit signal BOOT-EXIT that is enabled when a bootup operation is terminated based on the bootup control clock signal BCTR-CLK, the bootup control reset signal BCTR-RST, and the bootup control enable signal BCTR-EN. When the first transfer control signal TCTR<1> is enabled, the fuse circuit 212 generates the bootup counting signal BOOT-CNT that is sequentially counted after the start of a bootup operation based on the bootup control clock signal BCTR-CLK, the bootup control reset signal BCTR-RST, and the bootup control enable signal BCTR-EN.

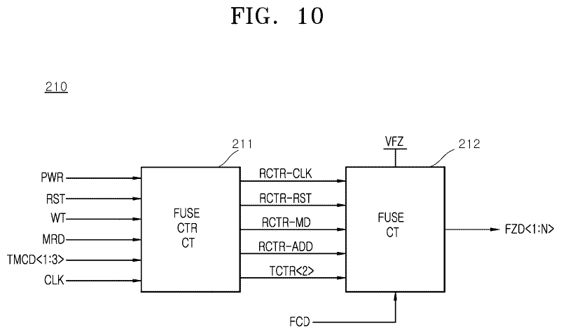

FIG. 10 is a diagram for describing a rupture operation of the fuse array circuit 210 according to an embodiment of the present disclosure.

The fuse control circuit 211 generates the rupture control clock signal RCTR-CLK, the rupture control reset signal RCTR_RST, the rupture control mode signal RCTR-MD, and the rupture control address RCTR-ADD, based on the power-up signal PWR, the write command WT, and the mode data MRD in synchronization with the clock signal CLK. The fuse control circuit 211 generates the second transfer control signal TCTR<2> that is enabled when the first to third test code signals TMCD<1:3> have a logic level combination that performs a rupture operation in synchronization with the clock signal CLK.

During an interval in which the second transfer control signal TCTR<2> is enabled and the fuse control command FCD is input during a set interval (5 μsec), the fuse circuit 212 programs the fuse data FZD<1:N> by cutting the E-fuse (E-FUSE in FIG. 5) that is selected among the plurality of E-fuses (E-FUSE in FIG. 5) based on the rupture control clock signal RCTR-CLK, the rupture control reset signal RCTR_RST, the rupture control mode signal RCTR-MD, and the rupture control address RCTR-ADD.

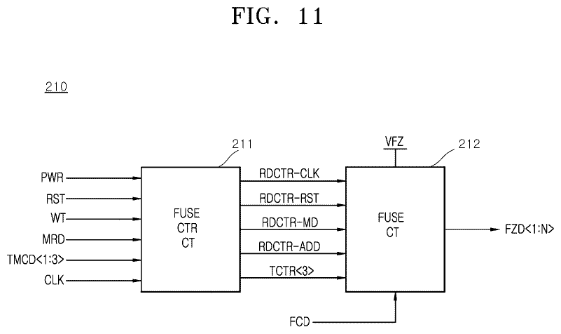

FIG. 11 is a diagram for describing a read operation of the fuse array circuit 210 according to an embodiment of the present disclosure.

The fuse control circuit 211 generates the read control clock signal RDCTR-CLK, the read control reset signal RDCTR_RST, the read control mode signal RDCTR-MD, and the read address RDCTR-ADD, based on the power-up signal PWR, the write command WT, and the mode data MRD in synchronization with the clock signal CLK. When the first to third test code signals TMCD<1:3> have a logic level combination that performs a read operation, the fuse control circuit 211 generates the third transfer control signal TCTR<3> that is enabled in synchronization with the clock signal CLK.

When the third transfer control signal TCTR<3> is enabled and the fuse control command FCD is input, the fuse circuit 212 outputs the fuse data FZD<1:N> programmed into the E-fuse (E-FUSE in FIG. 5) that is selected among the plurality of E-fuses (E-FUSE in FIG. 5), based on the read control clock signal RDCTR-CLK, the read control reset signal RDCTR_RST, the read control mode signal RDCTR-MD, and the read address RDCTR-ADD.

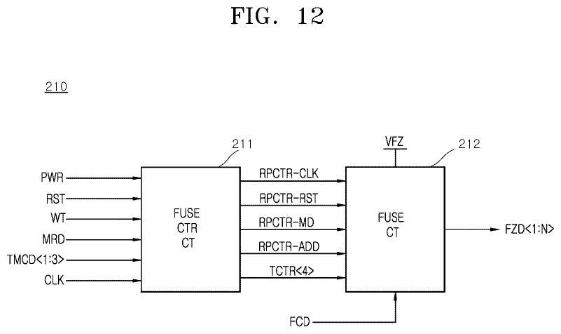

FIG. 12 is a diagram for describing a repair operation of the fuse array circuit 210 according to an embodiment of the present disclosure.

The fuse control circuit 211 generates the repair control clock signal RPCTR-CLK, the repair control reset signal RPCTR_RST, the repair control mode signal RPCTR-MD, and the repair control address RPCTR-ADD, based on the power-up signal PWR, the write command WT, and the mode data MRD in synchronization with the clock signal CLK. The fuse control circuit 211 generates the fourth transfer control signal TCTR<4> that is enabled when the first to third test code signals TMCD<1:3> have a logic level combination that performs a rupture operation in synchronization with the clock signal CLK.

When the fourth transfer control signal TCTR<4> is enabled and the fuse control command FCD is input, the fuse circuit 212 outputs the fuse data FZD<1:N> programmed into the E-fuse (E-FUSE in FIG. 5) that is selected among the plurality of E-fuses (E-FUSE in FIG. 5) based on the repair control clock signal RPCTR-CLK, the repair control reset signal RPCTR_RST, the repair control mode signal RPCTR-MD, and the repair control address RPCTR-ADD. The fuse circuit 212 performs a rupture operation again when the fuse data FZD<1:N> have a logic level combination different from a logic level combination of the mode data MRD.

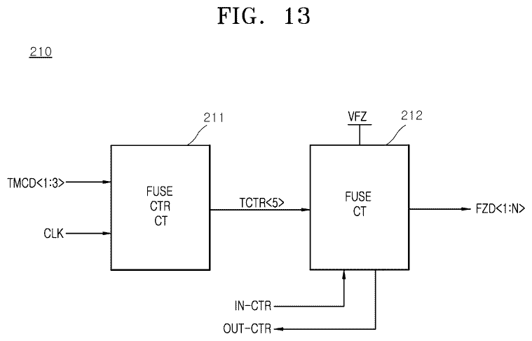

FIG. 13 is a diagram for describing a direct access operation of the fuse array circuit 210 according to an embodiment of the present disclosure.

The fuse control circuit 211 generates the fifth transfer control signal TCTR<5> that is enabled when the first to third test code signals TMCD<1:3> have a logic level combination that performs a direct access operation in synchronization with the clock signal CLK.

When the fifth transfer control signal TCTR<5> is enabled, the fuse circuit 212 outputs the fuse data FZD<1:N> programmed into the E-fuse (E-FUSE in FIG. 5) that is selected among the plurality of E-fuses (E-FUSE in FIG. 5) based on the input control signal IN-CTR. The fuse circuit 212 outputs the fuse data FZD<1:N> as the output control signal OUT-CTR. In this case, the fuse circuit 212 may detect that a rupture operation is not performed when the output control signal OUT-CTR does not have a preset logic level combination. When the output control signal OUT-CTR has a preset logic level combination, the fuse circuit 212 may detect that a rupture operation is performed. Furthermore, when the output control signal OUT-CTR output by the input control signal IN-CTR does not have a preset logic level combination, the fuse circuit 212 may detect that a failure occurs in the bootup control circuit 212-1, the rupture control circuit 212-2, the read control circuit 212-3, or the repair control circuit 212-4. When a failure occurs in the bootup control circuit 212-1, the rupture control circuit 212-2, the read control circuit 212-3, or the repair control circuit 212-4, the output control signal OUT-CTR having a preset logic level combination might not be output because a bootup operation, a read operation, a rupture operation, or a repair operation that is performed in the fuse cell array area 212-5 is not properly performed. As described above, the base chip 120 of the memory system 1 according to an embodiment of the present disclosure can efficiently control an operation of the fuse array circuit by controlling the fuse array circuit through a direct access operation or performing any one of a bootup operation, a rupture operation, a read operation, and a repair operation on the fuse array circuit by the fuse control command after a power-up operation is completed. After the start of a direct access operation, the base chip 120 of the memory system 1 may detect whether a rupture operation of the fuse array circuit is performed by applying a signal that controls an operation of the fuse array through the pad and then receiving the fuse data through the pad. After the start of a direct access operation, the base chip 120 of the memory system 1 may detect a failure in the control circuits included in the fuse array circuit by applying a signal that controls an operation of the fuse array through the pad and then receiving the fuse data through the pad. The operation of detecting a failure in the control circuits included in the fuse array circuit may include detecting whether a rupture operation is performed and detecting a failure in the control circuits by applying a signal that controls an operation of another fuse array and then receiving the fuse data through the pad. After the start of a direct access operation, the base chip 120 of the memory system 1 may distinguish between a failure in the fuse cell array area included in the fuse array circuit and a failure in the control circuits by applying a signal that controls an operation of the fuse array through the pad and then receiving the fuse data through the pad. The operation of distinguishing between a failure in the fuse cell array area included in the fuse array circuit and a failure in the control circuits may include detecting a failure in the fuse cell array area by detecting whether a rupture operation is performed and then detecting a failure in the control circuits by applying a signal that controls an operation of another fuse array and then receiving the fuse data through the pad.

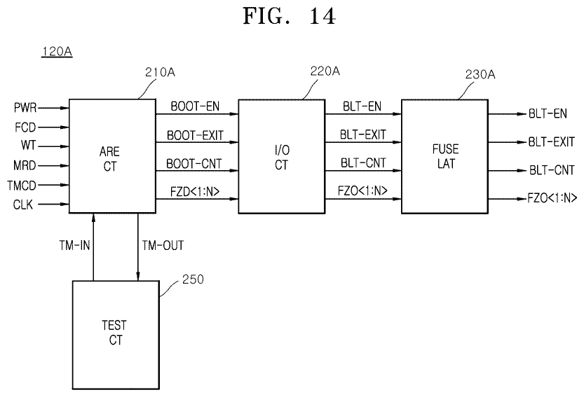

FIG. 14 is a block diagram illustrating a construction of the base chip 120 according to another embodiment of the present disclosure. As illustrated in FIG. 14, a base chip 120A may include a fuse array circuit (ARE CT) 210A, an input and output circuit (I/O CT) 220A, a fuse latch circuit (FUSE LAT) 230A, and a test circuit (TEST CT) 250.

The fuse array circuit 210A may perform any one of a bootup operation, a rupture operation, a read operation, and a repair operation on a plurality of E-fuses (E-FUSE in FIG. 5), based on a power-up signal PWR, a fuse control command FCD, a write command WT, a mode data MRD, and a test code signal TMCD in synchronization with a clock signal CLK. The power-up signal PWR may be set as a signal that is enabled when a power-up operation is completed. The power-up operation may be set as an operation in which the voltage level of an internal voltage that is used within the memory device 17 rises based on the level of a source voltage that is supplied from the outside of the memory system 1. The power-up signal PWR may be enabled when the voltage level of the internal voltage rises up to a set voltage level. The fuse control command FCD may be set as a command that is input in order to perform a rupture operation, a read operation, and a repair operation. The fuse control command FCD may be input every set interval (5 μsec) after the start of a rupture operation. The set interval may be set as a time interval during which a plurality of E-fuses (E-FUSE in FIG. 5) is cut by a fuse voltage (VFZ in FIG. 5). The write command WT may be set as a command that receives the mode data MRD. The mode data MRD may be set as a signal including address information that selects the plurality of E-fuses after the start of a rupture operation, a read operation, and a repair operation. The test code signal TMCD may be set as a signal including a plurality of bits. The test code signal TMCD may include a plurality of bits that sets a bootup operation, a rupture operation, a read operation, a repair operation, and a test operation. The test operation may be set as an operation of controlling an operation of the fuse array circuit 210 through the test circuit 250A and detecting whether a rupture operation is performed on the fuse array circuit 210A. The test circuit 250 may be implemented with a test circuit included in the memory system 1, such as IEEE1500, and an external test circuit. Unlike a direct access operation, the test operation may be set as an operation of controlling an operation of the fuse array circuit 210A through the test circuit 250 included in the fuse array circuit 210A instead of the DA pad area 240 and detecting whether a rupture operation is performed on the fuse array circuit 210A.

The fuse array circuit 210A may output fuse data FZD<1:N> programmed into the plurality of E-fuses (E-FUSE in FIG. 5) by performing a bootup operation based on the power-up signal PWR that is enabled when a power-up operation is completed. The fuse array circuit 210A may output a bootup enable signal BOOT-EN, a bootup exit signal BOOT-EXIT, and a bootup counting signal BOOT-CNT by performing a bootup operation based on the power-up signal PWR that is enabled when a power-up operation is completed. The bootup enable signal BOOT-EN may be set as a signal that is enabled during a bootup operation interval. The bootup exit signal BOOT-EXIT may be set as a signal that is enabled when a bootup operation is terminated. The bootup counting signal BOOT-CNT may be set as a signal that is sequentially counted after the start of a bootup operation and that includes location information of the plurality of E-fuses. The number N of bits of the fuse data FZD<1:N> may be set as a positive integer greater than 0. The number of bits of the fuse data FZD<1:N> may be set as various numbers of bits according to an embodiment.

The fuse array circuit 210A may program the fuse data FZD<1:N> by cutting the plurality of E-fuses (E-FUSE in FIG. 5) after the start of a rupture operation based on the fuse control command FCD and the test code signal TMCD. When the fuse control command FCD is input and the test code signal TMCD has a logic level combination for a rupture operation, the fuse array circuit 210A may program the fuse data FZD<1:N> by cutting the E-fuse (E-FUSE in FIG. 5) that is selected by the mode data MRD, among the plurality of E-fuses (E-FUSE in FIG. 5). When the fuse control command FCD is input and the test code signal TMCD has a logic level combination for a rupture operation, the fuse array circuit 210A may program the fuse data FZD<1:N> by cutting the E-fuse (E-FUSE in FIG. 5) by applying the fuse voltage (VFZ in FIG. 5) to the E-fuse (E-FUSE in FIG. 5) that is selected among the plurality of E-fuses (E-FUSE in FIG. 5) during a set interval.

After the start of a read operation, the fuse array circuit 210A may output programmed fuse data FZD<1:N> based on the fuse control command FCD and the test code signal TMCD. When the fuse control command FCD is input and the test code signal TMCD has a logic level combination for a read operation, the fuse array circuit 210A may detect whether a rupture operation is performed by detecting the logic level of the fuse data FZD<1:N>. For example, after the start of a read operation, when the fuse data FZD<1:N> does not have a preset logic level combination, the fuse array circuit 210A may detect that a rupture operation is not performed. The preset logic level combination may be set as the same logic level combination as the mode data MRD, and may be set as various logic level combinations according to an embodiment.

After the start of a repair operation, the fuse array circuit 210A may output the fuse data FZD<1:N> programmed by a rupture operation based on the fuse control command FCD and the test code signal TMCD. When the fuse control command FCD is input and the test code signal TMCD has a logic level combination for a repair operation, the fuse array circuit 210A may perform a rupture operation again by detecting the logic level of the fuse data FZD<1:N>. For example, after the start of a repair operation, when the fuse data FZD<1:N> do not have the same logic level combination as the mode data MRD, the fuse array circuit 210A may program the fuse data FZD<1:N> by cutting another E-fuse (E-FUSE in FIG. 5).

After the start of a test operation, the fuse array circuit 210A may output the fuse data FZD<1:N> programmed by a rupture operation as the test output signal TM-OUT based on a test input signal TM-IN. The fuse array circuit 210A may output a test output signal TM-OUT generated from the fuse data FZD<1:N> programmed into the E-fuse (E-FUSE in FIG. 5) that is selected among the plurality of E-fuses (E-FUSE in FIG. 5), based on the test input signal TM-IN.

The input and output circuit 220A may generate a bootup latch enable signal BLT-EN, a bootup latch exit signal BLT-EXIT, a bootup latch counting signal BLT-CNT, and fuse output data FZO<1:N>, based on the bootup enable signal BOOT-EN, the bootup exit signal BOOT-EXIT, the bootup counting signal BOOT-CNT, and the fuse data FZD<1:N>. The input and output circuit 220A may output the bootup enable signal BOOT-EN as the bootup latch enable signal BLT-EN. The input and output circuit 220A may output the bootup exit signal BOOT-EXIT as the bootup latch exit signal BLT-EXIT. The input and output circuit 220A may output the bootup counting signal BOOT-CNT as the bootup latch counting signal BLT-CNT. The input and output circuit 220A may output the fuse data FZD<1:N> as the fuse output data FZO<1:N>.

The fuse latch circuit 230A may latch the bootup latch enable signal BLT-EN, the bootup latch exit signal BLT-EXIT, the bootup latch counting signal BLT-CNT, and the fuse output data FZO<1:N>. The fuse latch circuit 230A may output the bootup latch enable signal BLT-EN, the bootup latch exit signal BLT-EXIT, and the bootup latch counting signal BLT-CNT, which are latched, to the outside of the base chip 120A. The fuse latch circuit 230A may output the bootup latch enable signal BLT-EN, the bootup latch exit signal BLT-EXIT, and the bootup latch counting signal BLT-CNT to the processor 19. The fuse latch circuit 230A may output the bootup latch enable signal BLT-EN, the bootup latch exit signal BLT-EXIT, and the bootup latch counting signal BLT-CNT to a test device (not illustrated). The fuse latch circuit 230A may control various test modes based on the fuse output data FZO<1:N> latched. For example, the fuse latch circuit 230A may control a test mode in which a chip ID that selects the plurality of core chips 121-1 to 121-L is changed, based on the latched fuse output data FZO<1:N>. The fuse latch circuit 230A may control various test modes in which a delay quantity by which the signals of the plurality of core chips 121-1 to 121-L are delayed, based on the fuse output data FZO<1:N> latched. The fuse latch circuit 230A may control a test mode in which a memory cell of the plurality of core chips 121-1 to 121-L is substituted, based on the fuse output data FZO<1:N> latched.

The test circuit 250 may output the test input signal TM-IN, that is, information that performs a test operation on the fuse array circuit 210A, to the fuse array circuit 210A. After the start of a test operation, when the test output signal TM-OUT generated from the fuse data FZD<1:N> has the same logic level combination as the mode data MRD, the test circuit 250 may detect that a rupture operation is performed on the E-fuse (E-FUSE in FIG. 5). After the start of a test operation, when the test output signal TM-OUT generated from the fuse data FZD<1:N> has a logic level combination different from a logic level combination of the mode data MRD, the test circuit 250 may detect that a rupture operation is not performed on the E-fuse (E-FUSE in FIG. 5). The test input signal IN-CTR and the test output signal TM-OUT may each be set as a signal including a plurality of bits.

As described above, the base chip 120 of the memory system 1 according to an embodiment of the present disclosure can efficiently control an operation of the fuse array circuit by controlling the fuse array circuit through a test operation or performing any one of a bootup operation, a rupture operation, a read operation, and a repair operation on the fuse array circuit by the fuse control command after a power-up operation is completed. After the start of a test operation, the base chip 120 of the memory system 1 may detect whether a rupture operation of the fuse array circuit is performed by applying a signal that controls an operation of the fuse array through the test circuit included in the base chip 120 and then receiving the fuse data through the pad. After the start of a test operation, the base chip 120 of the memory system 1 may detect a failure in the control circuits included in the fuse array circuit by applying a signal that controls an operation of the fuse array through the test circuit included in the base chip 120 and then receiving the fuse data through the test circuit. After the start of a test operation, the base chip 120 of the memory system 1 may distinguish a failure in the fuse cell array area included in the fuse array circuit and a failure in the control circuits by applying a signal that controls an operation of the fuse array through the test circuit and then receiving the fuse data through the test circuit.

What is claimed is:

1. An integrated circuit comprising:
a direct access (DA) pad area configured to generate an input control signal by receiving an external input signal from an outside of the integrated circuit through a plurality of pads, configured to generate an external output signal in response to receiving an output control signal, and configured to output the external output signal to the outside of the integrated circuit through the plurality of pads; and
a fuse array circuit configured to generate fuse data by performing any one of a bootup operation, a rupture operation, a read operation, and a repair operation on a plurality of electronic fuses (E-fuses) based on a power-up signal and a fuse control command and configured to generate the output control signal from the fuse data,
wherein the fuse array circuit detects whether the rupture operation is performed based on the input control signal after a start of a direct access operation.

2. The integrated circuit of claim 1, wherein:
the fuse array circuit performs the bootup operation when a power-up operation is completed, and
the fuse array circuit performs any one of the rupture operation, the read operation, and the repair operation based on a test code signal when the fuse control command is input.

3. The integrated circuit of claim 1, wherein the direct access operation is an operation of detecting whether the rupture operation of the fuse array circuit is performed through the plurality of pads.

4. The integrated circuit of claim 1, wherein the fuse array circuit programs the fuse data by cutting the plurality of E-fuses whenever the fuse control command is input after a set interval in the rupture operation and cuts the plurality of E-fuses by supplying a fuse voltage during the set interval.

5. The integrated circuit of claim 1, wherein:
the fuse array circuit outputs the fuse data programmed into the plurality of E-fuses after the start of the bootup operation,
the fuse array circuit programs the fuse data by cutting the plurality of E-fuses after the start of the rupture operation,
the fuse array circuit outputs the fuse data stored in the plurality of E-fuses after the start of the read operation and detects whether the rupture operation is performed by detecting a logic level combination of the fuse data, and
the fuse array circuit outputs the fuse data stored in the plurality of E-fuses after the start of the repair operation, detects whether the rupture operation is performed by detecting a logic level combination of the fuse data, and programs the fuse data again by cutting an E-fuse that has not been cut, among the plurality of E-fuses, when the rupture operation is not performed.

6. The integrated circuit of claim 1, wherein the fuse array circuit comprises:
a fuse control circuit configured to generate a bootup control signal, a rupture control signal, a read control signal, a repair control signal and a transfer control signal, based on the power-up signal, the fuse control command, the write command, the mode data, and a test code signal in synchronization with a clock signal; and
a fuse circuit configured to generate a bootup enable signal, a bootup exit signal, a bootup counting signal, and the fuse data by performing the bootup operation based on the bootup control signal, configured to generate the fuse data by performing the rupture operation based on the rupture control signal when the fuse control command is input, configured to generate the fuse data by performing the read operation based on the read control signal when the fuse control command is input, configured to generate the fuse data by performing the repair operation based on the repair control signal when the fuse control command is input, and configured to generate the fuse data based on the input control signal.

7. The integrated circuit of claim 1, wherein the DA pad area comprises:
a first pad configured to generate the input control signal by receiving the external input signal; and
a second pad configured to generate the external output signal by receiving the output control signal and configured to output the external output signal to the outside of the integrated circuit,
wherein the first pad and the second pad are at least any one of the plurality of pads.

8. An integrated circuit comprising:
a direct access (DA) pad area configured to generate an input control signal by receiving an external input signal from an outside of the integrated circuit through a plurality of pads, configured to generate an external output signal in response to receiving an output control signal, and configured to output the external output signal to the outside of the integrated circuit through the plurality of pads; and
a fuse array circuit configured to perform a bootup operation of outputting fuse data programmed into a plurality of electronic fuses (E-fuses) based on a power-up signal and configured to perform a rupture operation of programming the fuse data by cutting the plurality of E-fuses based on a fuse control command,
wherein the fuse array circuit detects whether the rupture operation is performed based on the input control signal after a start of a direct access operation.

9. The integrated circuit of claim 8, wherein the fuse array circuit programs the fuse data by cutting the plurality of E-fuses whenever the fuse control command is input after a set interval in the rupture operation and cuts the plurality of E-fuses by supplying a fuse voltage during the set interval.

10. The integrated circuit of claim 8, wherein the fuse array circuit comprises:
a fuse control circuit configured to generate a bootup control clock signal, a rupture control clock signal, a bootup control enable signal, and a rupture control mode signal when the power-up signal is enabled in synchronization with a clock signal and configured to generate a bootup control reset signal and a rupture control reset signal when a reset signal is enabled; and
a fuse circuit configured to generate a bootup enable signal, a bootup exit signal, a bootup counting signal, and the fuse data by performing the bootup operation based on the bootup control clock signal and the bootup control enable signal, configured to generate the fuse data by performing the rupture operation based on the rupture control clock signal and the rupture control reset signal when the fuse control command is input, and configured to generate the fuse data based on the input control signal.

11. The integrated circuit of claim 10, wherein the fuse control circuit comprises:
a mode control circuit configured to generate the bootup control clock signal, the rupture control clock signal, the bootup control enable signal, and the rupture control mode signal when the power-up signal is enabled in synchronization with the clock signal and configured to generate the bootup control reset signal and the rupture control reset signal when the reset signal is enabled;
an address generation circuit configured to generate a rupture address based on mode data when a write command is enabled in synchronization with the clock; and
a test control circuit configured to generate first to third transfer control signals based on a test code signal in synchronization with the clock.

12. The integrated circuit of claim 11, wherein the fuse circuit comprises:
a bootup control circuit configured to generate a bootup internal-driving signal, a bootup internal-enable signal, a bootup internal-standby signal, a bootup internal-address and a bootup internal-exit signal that perform the bootup operation based on the bootup control clock signal, the bootup control enable signal, and the bootup control reset signal;
a rupture control circuit configured to generate a rupture internal-driving signal and a rupture internal-enable signal, based on the rupture control clock signal, the rupture control mode signal, and the rupture control reset signal; and
a fuse cell array area configured to generate a bootup enable signal, a bootup exit signal, a bootup counting signal, and the fuse data by performing the bootup operation based on the bootup internal-driving signal, the bootup internal-enable signal, the bootup internal-standby signal, the bootup internal-address, and the bootup internal-exit signal when the first transfer control signal is enabled, configured to generate the fuse data by performing the rupture operation based on the rupture internal-driving signal and the rupture internal-enable signal when the second transfer control signal is enabled, configured to generate the fuse data based on the input control signal when the third transfer control signal is enabled, and configured to generate the output control signal from the fuse data.

13. The integrated circuit of claim 12, wherein the fuse cell array area comprises:
a transfer circuit configured to output the bootup internal-driving signal, the bootup internal-enable signal, the bootup internal-exit signal, the bootup internal-address, and the bootup internal-standby signal as transfer fuse data when the first transfer control signal is enabled, configured to output the rupture internal-driving signal and the rupture internal-enable signal as transfer fuse data when the second transfer control signal is enabled, configured to output the input control signal as the transfer fuse data when the third transfer control signal is enabled, and configured to output the fuse data as the output control signal; and
a fuse area configured to generate the bootup enable signal, the bootup exit signal, the bootup counting signal, and the fuse data by performing the bootup operation based on the transfer fuse data, configured to generate the fuse data by performing the rupture operation based on the transfer fuse data, and configured to generate the fuse data by performing a repair operation based on the transfer fuse data.

14. The integrated circuit of claim 8, wherein the DA pad area comprises:
a first pad configured to generate the input control signal by receiving the external input signal; and
a second pad configured to generate the external output signal by receiving the output control signal, configured to output the external output signal to the outside of the integrated circuit,
wherein the first pad and the second pad are at least any one of the plurality of pads.

15. A memory device comprising:
a first micro bump configured to generate an input control signal by receiving an external input signal from an outside of the memory device;
a second micro bump configured to generate an external output signal in response to receiving an output control signal and configured to output the external output signal to the outside of the memory device; and
a base chip electrically connected to the first micro bump and the second micro bump, configured to generate fuse data by performing a bootup operation and a rupture operation on a plurality of electronic fuses (E-fuses) based on a power-up signal and a fuse control command, configured to generate the output control signal from the fuse data and to output the output control signal to the second micro bump, and configured to detect whether the rupture operation is performed based on the input control signal received through the first micro bump.

16. The memory device of claim 15, further comprising a plurality of core chips vertically stacked on the base chip, wherein the base chip inputs and outputs data by controlling operations of the plurality of core chips.

17. The memory device of claim 15, wherein:
the base chip performs the bootup operation after a start of a power-up operation, and
the base chip performs the rupture operation based on a test code signal when the fuse control command is input.

18. The memory device of claim 15, wherein:
the base chip further comprises a fuse array circuit configured to perform the bootup operation of outputting the fuse data programmed into the plurality of E-fuses based on the power-up signal and configured to perform the rupture operation of programming the fuse data by cutting the plurality of E-fuses based on the fuse control command, and
the fuse array circuit detects whether the rupture operation is performed based on the input control signal.

19. The memory device of claim 18, wherein the fuse array circuit programs the fuse data by cutting the plurality of E-fuses whenever the fuse control command is input after a set interval in the rupture operation, and cuts the plurality of E-fuses by supplying a fuse voltage during the set interval.

20. The memory device of claim 18, wherein the fuse array circuit comprises:
a fuse control circuit configured to generate a bootup control clock signal, a rupture control clock signal, a bootup control enable signal, and a rupture control mode signal when the power-up signal is enabled in synchronization with a clock signal and configured to generate a bootup control reset signal and a rupture control reset signal when a reset signal is enabled; and
a fuse circuit configured to generate a bootup enable signal, a bootup exit signal, a bootup counting signal, and the fuse data by performing the bootup operation based on the bootup control clock signal and the bootup control enable signal, configured to generate the fuse data by performing the rupture operation based on the rupture control clock signal and the rupture control reset signal when the fuse control command is input, and configured to generate the fuse data based on the input control signal.

21. The memory device of claim 20, wherein the fuse control circuit comprises:
a mode control circuit configured to generate the bootup control clock signal, the rupture control clock signal, the bootup control enable signal, and the rupture control mode signal when the power-up signal is enabled in synchronization with the clock signal and configured to generate the bootup control reset signal and the rupture control reset signal when the reset signal is enabled;
an address generation circuit configured to generate a rupture address based on mode data when a write command is enabled in synchronization with the clock; and
a test control circuit configured to generate first to third transfer control signals based on a test code signal in synchronization with the clock.

22. The memory device of claim 21, wherein the fuse circuit comprises:
a bootup control circuit configured to generate a bootup internal-driving signal, a bootup internal-enable signal, a bootup internal-exit signal, a bootup internal-address and a bootup internal-standby signal that perform the bootup operation based on the bootup control clock signal, the bootup control enable signal, and the bootup control reset signal;
a rupture control circuit configured to generate a bootup internal-driving signal and a rupture internal-enable signal, based on the rupture control clock signal, the rupture control mode signal, and the rupture control reset signal; and
a fuse cell array area configured to generate a bootup enable signal, a bootup exit signal, a bootup counting signal, and the fuse data by performing the bootup operation based on the bootup internal-driving signal, the bootup internal-enable signal, the bootup internal-exit signal, the bootup internal-address, and the bootup internal-standby signal when the first transfer control signal is enabled, configured to generate the fuse data by performing the rupture operation based on the rupture internal-driving signal and the rupture internal-enable signal when the second transfer control signal is enabled, configured to generate the fuse data based on the input control signal when the third transfer control signal is enabled, and configured to generate the output control signal from the fuse data.

23. The memory device of claim 22, wherein the fuse cell array area comprises:
a transfer circuit configured to output the bootup internal-driving signal, the bootup internal-enable signal, the bootup internal-exit signal, the bootup internal-address, and the bootup internal-standby signal as transfer fuse data when the first transfer control signal is enabled, configured to output the rupture internal-driving signal and the rupture internal-enable signal as transfer fuse data when the second transfer control signal is enabled, configured to output the input control signal as the transfer fuse data when the third transfer control signal is enabled, and configured to output the fuse data as the output control signal; and
a fuse area configured to generate the bootup enable signal, the bootup exit signal, the bootup counting signal, and the fuse data by performing the bootup operation based on the transfer fuse data, configured to generate the fuse data by performing the rupture operation based on the transfer fuse data, and configured to generate the fuse data by performing a repair operation based on the transfer fuse data.
